(19) United States
(12) Patent Application Publication
(10) Pub. No.: US 2010/0124140 A1
(43) Pub. Date: May 20, 2010

(54) POWER SUPPLY CIRCUIT AND NAND-TYPE FLASH MEMORY

(75) Inventors: Takahiro Otsuka, Yokohama-Shi (JP); Toshifumi Hashimoto, Yokohama-Shi (JP)

Correspondence Address: OBLON, SPIVAK, MCCLELLAND MAIER & NEUSTADT, L.L.P., 1940 DUKE STREET, ALEXANDRIA, VA, 22314, US

(73) Assignee: KABUSHIKI KAISHA TOSHIBA, Tokyo (JP)

(21) Appl. No.: 12/544,349

(22) Filed: Aug. 20, 2009

(30) Foreign Application Priority Data
Nov. 20, 2008 (JP) 2008-296473

(51) Int. Cl. G11C 5/14; G05F 1/00

(52) U.S. Cl. 365/226; 323/265

(57) ABSTRACT

A power supply circuit has a control circuit. The control circuit outputs a control clock signal so as to cause a first booster circuit to compulsorily perform boosting operation with a first boosting capability in response to an output signal of a second comparison amplifier after a lapse of a prescribed period since the first booster circuit is started to perform boosting operation with the first boosting capability in response to a first activation signal of a first comparison amplifier.

### CROSS-REFERENCE TO RELATED APPLICATION

This application is based upon and claims the benefit of priority from the prior Japanese Patent Application No. 2008-296473, filed on Nov. 20, 2008, the entire contents of which are incorporated herein by reference.

### BACKGROUND OF THE INVENTION

1. Field of the Invention

The present invention relates to power supply circuits having booster circuits for boosting power supply voltage and NAND (not and)-type flash memories.

2. Background Art

There have been power supply circuits in which a power supply voltage is boosted by a booster circuit and the boosted power supply voltage is supplied to a nonvolatile semiconductor storage device, such as a NAND-type electrically erasable programmable read only memory (EEPROM).

One of such conventional power supply circuits includes a VPP booster circuit that boosts a voltage supplied from a power supply to produce an output voltage, a resistance circuit for monitoring the output voltage, and a comparison detection circuit that outputs a signal for instruction to activate or inactivate the VPP booster circuit, based on the value of a monitor voltage obtained by the resistance circuit (for example, see Japanese Patent Laid-Open No. 2003-199329).

In this power supply circuit, if the output voltage is decreased by connection of a load, the comparison detection circuit detects the decrease in output voltage and outputs a signal for activation to the VPP booster circuit to cause the VPP booster circuit to perform boosting operation, thereby enabling the output voltage to return to its state of a desired voltage value.

Another one of conventional power supply circuits further includes an n-metal oxide semiconductor (nMOS) transistor connected between the VPP booster circuit and the output terminal, and a local booster circuit that applies a voltage obtained by boosting an output of the VPP booster circuit to the gate of the nMOS transistor.

In this circuit, if the boosting operation of the local booster circuit is slower than that of the VPP booster circuit, a large potential difference is produced between the gate and the source of the nMOS transistor, for example, when the voltage is boosted from 0 V to a high value (e.g., 26 V). This can results in dielectric breakdown of the nMOS transistor.

### SUMMARY OF THE INVENTION

According to one aspect of the present invention, there is provided: a power supply circuit comprising:

an output terminal which outputs a set voltage;

a first booster circuit which boosts and outputs a voltage supplied from a power supply;

an nMOS transistor which is connected between output of the first booster circuit and the output terminal;

a second booster circuit which boosts the voltage output by the first booster circuit and outputs the boosted voltage to a gate of the nMOS transistor;

a voltage divider circuit which outputs a first monitor voltage obtained by dividing a voltage output from the output terminal in accordance with a first voltage ratio, and outputs a second monitor voltage obtained by dividing a voltage output from the output terminal in accordance with a second voltage ratio, the second voltage ratio is smaller than the first voltage ratio;

a first comparison amplifier which compares a reference voltage with the first monitor voltage, and outputs a first activation signal if the first monitor voltage is lower than the reference voltage;

a second comparison amplifier which compares the reference voltage with the second monitor voltage, and outputs a second activation signal if the second monitor voltage is lower than the reference voltage but outputs a second deactivation signal if the second monitor voltage is equal to or more than the reference voltage; and

a control circuit which outputs a control clock signal to the first booster circuit, the control clock signal causing the first booster circuit to perform boosting operation with a first boosting capability when the first activation signal is input, causing the first booster circuit to perform boosting operation with a second boosting capability lower than the first boosting capability when the first deactivation signal is input and the second activation signal is input, and causing the first booster circuit to be deactivated when the second deactivation signal is input,
wherein the control circuit outputs the control clock signal so as to cause the first booster circuit to compulsorily perform the boosting operation with the first boosting capability in response to the output signal of the second comparison amplifier after a lapse of a prescribed period since the first booster circuit is started to perform the boosting operation with the first boosting capability in response to the first activation signal of the first comparison amplifier.

According to another aspect of the present invention, there is provided: a power supply circuit comprising:

an output terminal which outputs a set voltage;

a first booster circuit which boosts and outputs a voltage supplied from a power supply;

an nMOS transistor which is connected between output of the first booster circuit and the output terminal;

a second booster circuit which boosts the voltage output by the first booster circuit and outputs the boosted voltage to a gate of the nMOS transistor;

a voltage divider circuit which outputs a first monitor voltage obtained by dividing a voltage output from the output terminal in accordance with a first voltage ratio, and outputs a second monitor voltage obtained by dividing a voltage output from the output terminal in accordance with a second voltage ratio, the second voltage ratio is smaller than the first voltage ratio;

a first comparison amplifier which compares a reference voltage with the first monitor voltage, and outputs a first activation signal if the first monitor voltage is lower than the reference voltage;

a second comparison amplifier which compares the reference voltage with the second monitor voltage, and outputs a second activation signal if the second monitor voltage is lower than the reference voltage but outputs a second deactivation signal if the second monitor voltage is equal to or more than the reference voltage; and

a control circuit which outputs a control clock signal to the first booster circuit, the control clock signal causing the first booster circuit to perform boosting operation with a first boosting capability when the first activation signal is input, causing the first booster circuit to perform boosting operation with a second boosting capability lower than the first boosting capability when the first deactivation signal is input and the second activation signal is input, and causing the first booster circuit to be deactivated when the second deactivation signal is input,
wherein after a lapse of a prescribed period since the first monitor voltage first exceeds the reference voltage after the first booster circuit is started to perform the boosting operation with the first boosting capability in response to the first activation signal of the first comparison amplifier, the control circuit outputs the control clock signal so as to cause the first booster circuit to compulsorily perform the boosting operation with the first boosting capability in response to the output signal of the second comparison amplifier.

According to still another aspect of the present invention, there is provided: a NAND-type flash memory comprising:

a memory cell array;

a bit-line control circuit which writes and reads data to and from the memory cell array;

a row decoder which controls voltages of a control gate and a select gate for the memory cell array;

a substrate voltage control circuit which controls a voltage of a substrate having the memory cell array formed thereon; and

a power supply circuit which boosts a voltage supplied from a power supply and supplies the boosted voltage to the bit-line control circuit, the row decoder and the substrate voltage control circuit,
wherein the power supply circuit comprising:

an output terminal which outputs a set voltage;

a first booster circuit which boosts and outputs a voltage supplied from a power supply;

an nMOS transistor which is connected between output of the first booster circuit and the output terminal;

a second booster circuit which boosts the voltage output by the first booster circuit and outputs the boosted voltage to a gate of the nMOS transistor;

a voltage divider circuit which outputs a first monitor voltage obtained by dividing a voltage output from the output terminal in accordance with a first voltage ratio, and outputs a second monitor voltage obtained by dividing a voltage output from the output terminal in accordance with a second voltage ratio, the second voltage ratio is smaller than the first voltage ratio;

a first comparison amplifier which compares a reference voltage with the first monitor voltage, and outputs a first activation signal if the first monitor voltage is lower than the reference voltage;

a second comparison amplifier which compares the reference voltage with the second monitor voltage, and outputs a second activation signal if the second monitor voltage is lower than the reference voltage but outputs a second deactivation signal if the second monitor voltage is equal to or more than the reference voltage; and

a control circuit which outputs a control clock signal to the first booster circuit, the control clock signal causing the first booster circuit to perform boosting operation with a first boosting capability when the first activation signal is input, causing the first booster circuit to perform boosting operation with a second boosting capability lower than the first boosting capability when the first deactivation signal is input and the second activation signal is input, and causing the first booster circuit to be deactivated when the second deactivation signal is input,

wherein the control circuit outputs the control clock signal so as to cause the first booster circuit to compulsorily perform the boosting operation with the first boosting capability in response to the output signal of the second comparison amplifier after a lapse of a prescribed period since the first booster circuit is started to perform the boosting operation with the first boosting capability in response to the first activation signal of the first comparison amplifier.

According to still another aspect of the present invention, there is provided: a NAND-type flash memory comprising:

a memory cell array;

a bit-line control circuit which writes and reads data to and from the memory cell array;

a row decoder which controls voltages of a control gate and a select gate for the memory cell array;

a substrate voltage control circuit which controls a voltage of a substrate having the memory cell array formed thereon; and

a power supply circuit which boosts a voltage supplied from a power supply and supplies the boosted voltage to the bit-line control circuit, the row decoder and the substrate voltage control circuit,

wherein the power supply circuit comprising:

an output terminal which outputs a set voltage;

a first booster circuit which boosts and outputs a voltage supplied from a power supply;

an nMOS transistor which is connected between output of the first booster circuit and the output terminal;

a second booster circuit which boosts the voltage output by the first booster circuit and outputs the boosted voltage to a gate of the nMOS transistor;

a voltage divider circuit which outputs a first monitor voltage obtained by dividing a voltage output from the output terminal in accordance with a first voltage ratio, and outputs a second monitor voltage obtained by dividing a voltage output from the output terminal in accordance with a second voltage ratio, the second voltage ratio is smaller than the first voltage ratio;

a first comparison amplifier which compares a reference voltage with the first monitor voltage, and outputs a first activation signal if the first monitor voltage is lower than the reference voltage;

a second comparison amplifier which compares the reference voltage with the second monitor voltage, and outputs a second activation signal if the second monitor voltage is lower than the reference voltage but outputs a second deactivation signal if the second monitor voltage is equal to or more than the reference voltage; and

a control circuit which outputs a control clock signal to the first booster circuit, the control clock signal causing the first booster circuit to perform boosting operation with a first boosting capability when the first activation signal is input, causing the first booster circuit to perform boosting operation with a second boosting capability lower than the first boosting capability when the first deactivation signal is input and the second activation signal is input, and causing the first booster circuit to be deactivated when the second deactivation signal is input,
wherein after a lapse of a prescribed period since the first monitor voltage first exceeds the reference voltage after the first booster circuit is started to perform the boosting operation with the first boosting capability in response to the first activation signal of the first comparison amplifier, the control circuit outputs the control clock signal so as to cause the first booster circuit to compulsorily perform the boosting operation with the first boosting capability in response to the output signal of the second comparison amplifier.

### BRIEF DESCRIPTION OF THE DRAWINGS

FIG. 1 shows a configuration of main parts of a power supply circuit 100 according to a first embodiment, which is an aspect of the present invention;

FIG. 2 is a circuit diagram showing an example of a first booster circuit 2 applied to the power supply circuit 100 shown in FIG. 1;

FIG. 3 is a circuit diagram showing an example of a control circuit 9 applied to the power supply circuit 100 shown in FIG. 1;

FIG. 4 is a waveform chart showing waveforms of signals to control the boosting operation of the power supply circuit 100 according to the first embodiment of the present invention and a relationship between the signals and output of the power supply circuit; and

FIG. 5 is a block diagram showing an example of a NAND-type flash memory including a power supply circuit according to the first embodiment, which is an aspect of the present invention.

### DETAILED DESCRIPTION

Embodiments according to the present invention will be described below with reference to the accompanying drawings.

### First Embodiment

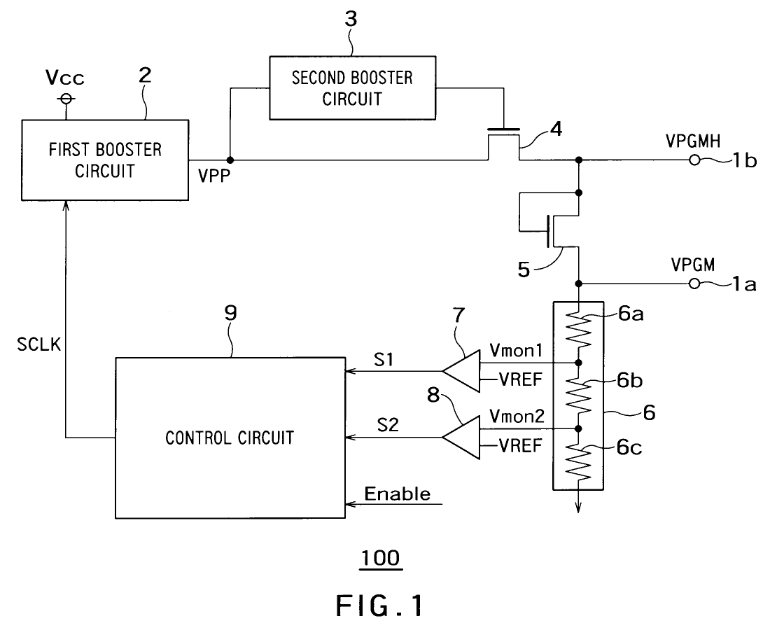

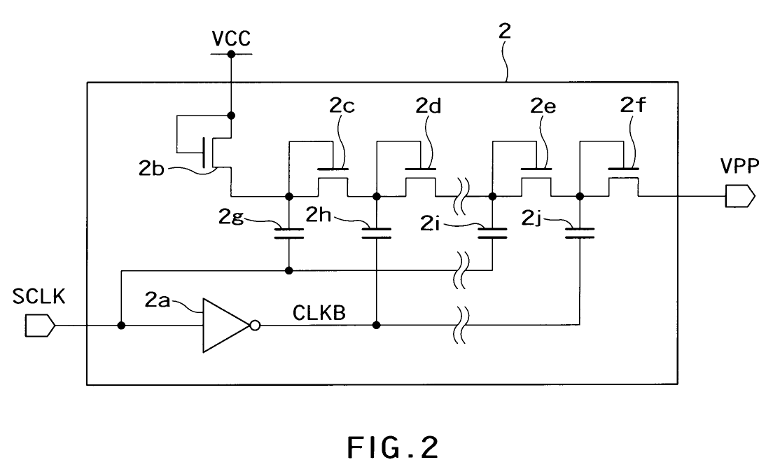

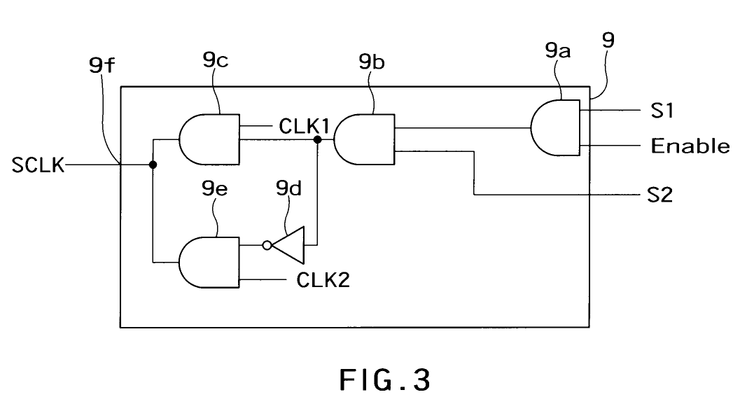

FIG. 1 shows the configuration of main parts of a power supply circuit 100 according to a first embodiment, which is an aspect of the present invention. FIG. 2 is a circuit diagram showing an example of a first booster circuit 2 applied to the power supply circuit 100 shown in FIG. 1. FIG. 3 is a circuit diagram showing an example of a control circuit 9 applied to the power supply circuit 100 shown in FIG. 1.

As shown in FIG. 1, the power supply circuit 100 includes an output terminal 1a, an output terminal 1b, the first booster circuit 2, a second booster circuit 3, an nMOS transistor 4, a diode 5, a voltage divider circuit 6, a first comparison amplifier 7, a second comparison amplifier 8 and the control circuit 9.

The output terminal 1a is a terminal for outputting an output voltage VPGM.

The output terminal 1b is a terminal for outputting an output voltage VPGMH higher than the output voltage VPGM.

The first booster circuit 2 boosts a voltage supplied from a power supply VCC and outputs a voltage VPP.

The nMOS transistor 4 is connected between the output of the first booster circuit 2 and the output terminals 1a and 1b. The voltage VPP drops in the nMOS transistor 4 and the output voltage VPGMH is output from the output terminal 1b. For example, a high breakdown voltage transistor is selected as the nMOS transistor 4.

The diode 5 is made of, for example, a diode-connected nMOS transistor. For example, a high breakdown voltage transistor is selected as the nMOS transistor.

Note that the voltage VPP drops in the nMOS transistor 4 and the diode 5, and the output voltage VPGM is output from the output terminal 1a.

There is a potential difference between the output voltage VPGMH and the output voltage VPGM. This potential difference corresponds to a threshold voltage of the nMOS transistor constituting the diode 5.

The second booster circuit 3 boosts the voltage VPP output by the first booster circuit 2 and outputs the boosted voltage to the gate of the nMOS transistor 4. The voltage output by the second booster circuit 3 increases to a threshold voltage of the nMOS transistor to turn the nMOS transistor on. This causes the voltage output by the first booster circuit 2 to be supplied to the output terminals 1a and 1b.

The voltage divider circuit 6 includes a first voltage dividing resistor 6a having one end connected to the output terminal 1a and having a resistance value R1, a second voltage dividing resistor 6b having one end connected to the other end of the first voltage dividing resistor 6a and having a resistance value R2, and a third voltage dividing resistor 6c having one end connected to the other end of the second voltage dividing resistor 6b and the other end connected to the ground and having a resistance value R3.

The voltage divider circuit 6 divides the output voltage VPGM output from the output terminal 1a in accordance with a first voltage ratio, (R2+R3)/(R1+R2+R3), and outputs a first monitor voltage Vmon1. Further, the voltage divider circuit 6 divides the output voltage VPGM output from the output terminal 1a in accordance with a second voltage ratio, (R3)/(R1+R2+R3), which is smaller than the first voltage ratio, and outputs a second monitor voltage Vmon2.

The first comparison amplifier 7 compares a reference voltage VREF with the first monitor voltage Vmon1. The first comparison amplifier 7 outputs a first activation signal S1 (“High” level) if the first monitor voltage Vmon1 is lower than the reference voltage VREF. On the other hand, the first comparison amplifier 7 outputs a first deactivation signal S1 (“Low” level) if the first monitor voltage Vmon1 is equal to or more than the reference voltage VREF.

The second comparison amplifier 8 compares the reference voltage VREF with the second monitor voltage Vmon2. The second comparison amplifier 8 outputs a second activation signal S2 (“High” level) if the second monitor voltage Vmon2 is lower than the reference voltage VREF. On the other hand, the second comparison amplifier 8 outputs a second deactivation signal S2 (“Low” level) if the second monitor voltage Vmon2 is equal to or more than the reference voltage VREF.

If the first activation signal S1 (“High” level) is input, the control circuit 9 outputs a control clock signal SCLK to the first booster circuit 2 so as to cause the first booster circuit 2 to perform the boosting operation with a first boosting capability A1.

If the first deactivation signal S1 (“Low” level) is input and the second activation signal S2 (“High” level) is input, the control circuit 9 outputs the control clock signal SCLK to the first booster circuit 2 so as to cause the first booster circuit 2 to perform the boosting operation with a second boosting capability A2 lower than the first boosting capability A1.

If the second deactivation signal S2 (“Low” level) is input, the control circuit 9 outputs the control clock signal SCLK to the first booster circuit 2 so as to deactivate the first booster circuit 2.

In particular, the control circuit 9 outputs the control clock signal SCLK in response to the first activation signal S1 (“High” level) of the first comparison amplifier 7 to cause the first booster circuit 2 to perform the boosting operation with the first boosting capability A1. After a lapse of a prescribed period T since the start of the boosting operation, the control circuit 9 outputs the control clock signal SCLK so as to cause the first booster circuit 2 to compulsorily perform the boosting operation with the first boosting capability A1 in response to the output signal of the second comparison amplifier 8.

Note that, for example, the control circuit 9 raises the frequency of the control clock signal SCLK when increasing the boosting capability of the first booster circuit 2. In contrast, the control circuit 9 reduces the frequency of the control clock signal SCLK when decreasing the first booster circuit 2. Accordingly, the frequency of the control clock signal SCLK is set lower with the second boosting capability A2 than with the first boosting capability A1.

Note that after a lapse of the prescribed period T since the first monitor voltage Vmon1 first exceeds the reference voltage VREF after the control circuit 9 causes the first booster circuit 2 to start the boosting operation with the first boosting capability A1 in response to the first activation signal S1 (“High” level) of the first comparison amplifier 7, the control circuit 9 may output the control clock signal SCLK to cause the first booster circuit 2 to perform the boosting operation with the first boosting capability A1 in response to the output signal S2 of the second comparison amplifier 8.

As shown in FIG. 2, the first booster circuit 2 includes, for example, an inverter circuit 2a to which the control clock signal SCLK is input and that outputs a reversed clock signal CLKB, a MOS transistor 2b having the source connected to the power supply VCC and having the gate connected to that source, MOS transistors 2c to 2f that are disposed in series between the drain of the MOS transistor 2b and an output terminal 1a, 1b and that each have the source and the gate connected to each other, and capacitors 2g to 2j connected to the sources of the MOS transistors 2c to 2f, respectively.

The control clock signal SCLK is input to the capacitors 2g and 2i, and the output of the inverter circuit 2a is connected to the capacitors 2h and 2j. As such, for example, the control clock signal SCLK is input to the first booster circuit 2, causing the MOS transistors 2c to 2f to alternately operate, so that the capacitors 2g to 2j are sequentially charged and boosted. The boosted voltage is output as the output voltage VPP.

Note that as described before, improvement in boosting operation performance of the first booster circuit 2 can be achieved by increasing the capacitances of the capacitors 2g and 2j. The first booster circuit 2 shown in FIG. 2 is illustrative, and a booster circuit applied to the present embodiment needs to boost the voltage supplied from the power supply VCC based on the input of the control clock signal SCLK.

As shown in FIG. 3, the control circuit 9 includes a first AND circuit 9a, a second AND circuit 9b, a third AND circuit 9c, an inverter circuit 9d, a fourth AND circuit 9e and a signal terminal 9f.

The first AND circuit 9a is configured such that an enable signal Enable and the output signal S1 of the first comparison amplifier 7 are input to the first AND circuit 9a.

The second AND circuit 9b is configured such that the output signal S2 of the second comparison amplifier 8 and an output signal of the first AND circuit 9a are input to the second AND circuit 9b.

The third AND circuit 9c is configured such that an output signal of the second AND circuit 9b and a first clock signal CLK1 are input to the third AND circuit 9c. The output of the third AND circuit 9c is connected to the signal terminal 9f.

The inverter circuit 9d is configured such that an output signal of the second AND circuit 9b is input to the inverter circuit 9d.

The fourth AND circuit 9e is configured such that an output signal of the inverter circuit 9d and a second clock signal CLK2 are input to the fourth AND circuit 9e. The output of the fourth AND circuit 9e is connected to the signal terminal 9f.

The signal terminal 9f outputs output signals of the third and fourth AND circuits 9c and 9e as the control clock signals SCLK.

Note that the frequency of the second clock signal CLK2 is set to be smaller than a frequency of the first clock signal before a lapse of the prescribed period T. Further, the frequency of the second clock signal CLK2 is set to be equal to that of the first clock signal CLK1 after the lapse of the prescribed period T.

Note that in the present embodiment, loads connected to the output terminals 1a and 1b include nonvolatile semiconductor storage devices, such as NAND cell, NOR cell, DINOR cell and AND cell-type EEPROMs, circuits that need voltage boosted to be more than the voltage of the power supply VCC, and so on.

Note also that the diode 5 and the output terminal 1b power may be omitted from the supply circuit 100.

Next, the boosting operation of the power supply circuit 100 having the configuration as described above will be described.

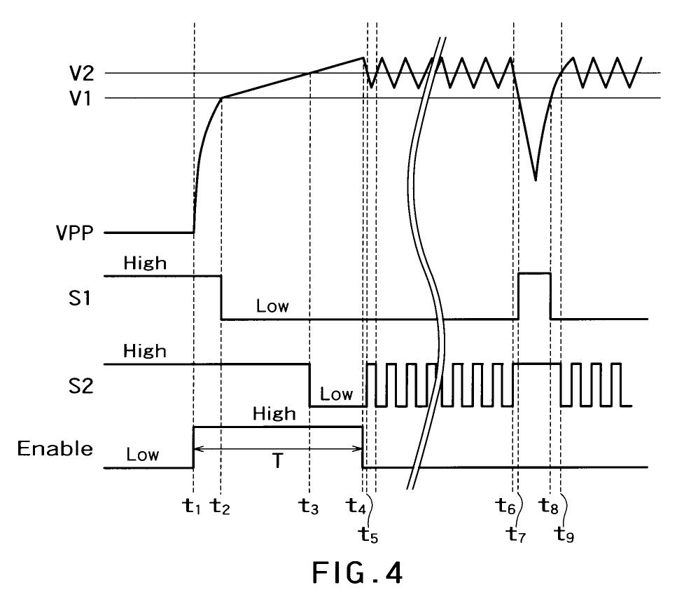

FIG. 4 is a waveform chart showing waveforms of signals to control the boosting operation of the power supply circuit 100 according to the first embodiment of the present invention and a relationship between the signals and output of the power supply circuit. Note that the waveforms (logics) of the signals are exemplary, and other logics may be used if they allow the power supply circuit 100 to perform in the same way.

Note that the enable signal Enable is at the “Low” level in its initial state. Further, the voltage VPP is 0 V, and therefore the output signal S1 of the first comparison amplifier 7 is at the “High” level (first activation signal), and the output signal S2 of the second comparison amplifier 8 is at the “High” level (second activation signal).

As shown in FIG. 4, first, the level of the enable signal Enable changes from the “Low” level to the “High” level at time to. Since the first activation signal S1 (“High” level) is input, the control circuit 9 outputs the control clock signal SCLK to the first booster circuit 2 so as to cause the first booster circuit 2 to start the boosting operation with the first boosting capability Al (time to to t2).

Thus, during a period from the time to to the time t2, the first booster circuit 2 performs the boosting operation with the first boosting capability A1. Accordingly, the voltage VPP is rapidly boosted to a voltage V1, which is the vicinity of a set voltage V2.

Next, at the time t2, the voltage VPP becomes equal to the voltage V1 (at this point, the first monitor voltage Vmon1 and the reference voltage VREF become equal). Thus, the first comparison amplifier 7 outputs the first deactivation signal 51 (“Low” level).

Thus, during a period from the time t2 to time t3, since the first deactivation signal S1 (“Low” level) is input and the second activation signal S2 (“High” level) is input, the control circuit 9 outputs the control clock signal SCLK to the first booster circuit 2 so as to cause the first booster circuit 2 to perform the boosting operation with the second boosting capability A2, which is lower than the first boosting capability A1.

On the other hand, at the time t3, the voltage VPP becomes equal to the set voltage V2. At this point, the second monitor voltage Vmon2 and the reference voltage VREF become equal. Thus, the second comparison amplifier 8 outputs the second deactivation signal S2 (“Low” level).

When the second deactivation signal S2 (“Low” level) is input, the control circuit 9 outputs the control clock signal SCLK to the first booster circuit 2 so as to deactivate the first booster circuit 2 (time t3 to t4).

Note that when the voltage VPP becomes equal to the set voltage V2, desired set voltages are output from the output terminals 1a and 1b.

As described above, during a period from the time t2 to time t4, the first booster circuit 2 performs the boosting operation with the second boosting capability A2 with the voltage VPP being in the vicinity of the set voltage V2.

Accordingly, if the boosting operation of the first booster circuit 2 is slower than that of the second booster circuit 3, it becomes difficult to produce a large potential difference between the gate and the source of the nMOS transistor in question, for example, when the voltage is boosted from 0 V to a high voltage (e.g., 26 V). This enables dielectric breakdown of the nMOS transistor 4 to be suppressed.

Next, at the time t4 when the prescribed period T has passed since time t1, the enable signal Enable changes from the “High” level to the “Low” level.

In response to the enable signal Enable (“Low” level), the control circuit 9 outputs the control clock signal SCLK so as to cause the first booster circuit 2 to compulsorily perform the boosting operation with the first boosting capability A1 in response to the output signal S2 of the second comparison amplifier 8.

Thus, after the time t4, first booster circuit 2 performs the boosting operation with the first boosting capability A1. Note that, after the time t4, the output of the second booster circuit 3 is also sufficiently boosted, and therefore dielectric breakdown as described before is unlikely to occur.

As described before, after the time t4, the control circuit 9 causes the first booster circuit 2 to perform the boosting operation with the first boosting capability A1, which is high. Therefore, for example, even if the voltage VPP largely decreases because of noise or the like at time t6, the voltage VPP steeply increases to rapidly return to the vicinity of the set voltage V2 (time t6 to t9).

Note that during a period from time t7 to time t8, the first comparison amplifier 7 outputs the first activation signal S1 (“High” level). As described before, however, since the enable signal Enable is at the “Low” level, the control circuit 9 causes the first booster circuit 2 to perform the boosting operation with the first boosting capability A1 in response to the second activation signal S2 (“High” level) despite the first activation signal S1 (“High” level).

As described above, with the power supply circuit 100 according to the present embodiment, dielectric breakdown of MOS transistors can be suppressed.

Next, description will be given on an example where the power supply circuit 100 according to the present embodiment as described above is applied to a NAND-type flash memory.

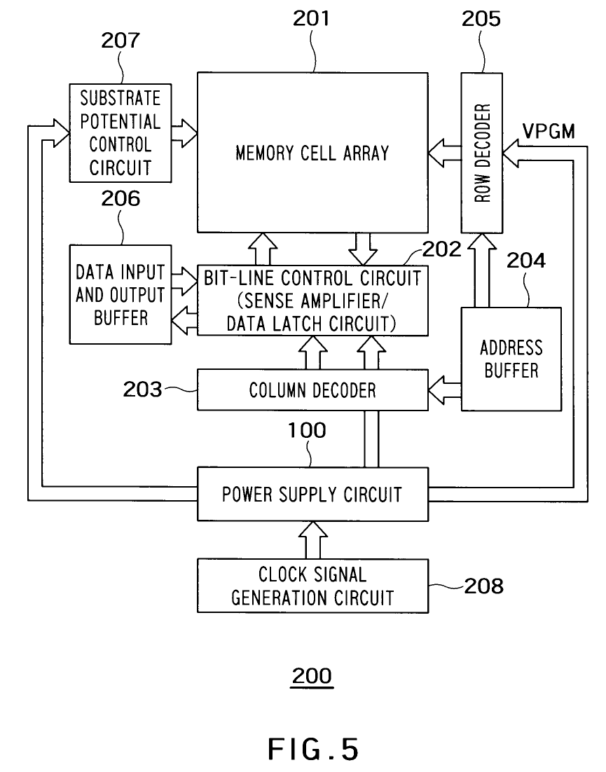

FIG. 5 is a block diagram showing an example of a NAND-type flash memory including a power supply circuit according to the first embodiment, which is an aspect of the present invention.

As shown in FIG. 5, a bit-line control circuit 202 for writing and reading data to and from a memory cell array 201, as a memory means, is provided in a semiconductor storage device 200, or a NAND-type flash memory.

The bit-line control circuit 202 is connected to a data input and output buffer 206. The bit-line control circuit 202 receives an output of a column decoder 203 that receives an address signal from an address buffer 204, as an input.

Provided for the memory cell array 201 are a row decoder 205 for controlling voltages of a control gate and a select gate, and a substrate voltage control circuit 207 for controlling the voltage of a p-type substrate (or p-type well) on which the memory cell array 201 is formed.

Further, the semiconductor storage device 200 includes a clock generation circuit 208 to generate clock signals, such as the first and second clock signals CLK1 and CLK2, and the power supply circuit 100 according to the present embodiment.

The power supply circuit 100 supplies the output voltage VPGM to the bit-line control circuit 202, the row decoder 205 and the substrate voltage control circuit 207 upon reading/writing/erasing of the memory cell array 201. Note that the output voltage VPGMH may be supplied from the power supply circuit 100 to the above each component as necessary.

The power supply circuit 100 can suppress dielectric breakdown of MOS transistors as described before.

Accordingly, with the NAND-type flash memory 200 according to the present embodiment, dielectric breakdown of MOS transistors can be suppressed.

What is claimed is:

1. A power supply circuit comprising:
an output terminal which outputs a set voltage;
a first booster circuit which boosts and outputs a voltage supplied from a power supply;
an nMOS transistor which is connected between output of the first booster circuit and the output terminal;
a second booster circuit which boosts the voltage output by the first booster circuit and outputs the boosted voltage to a gate of the nMOS transistor;
a voltage divider circuit which outputs a first monitor voltage obtained by dividing a voltage output from the output terminal in accordance with a first voltage ratio, and outputs a second monitor voltage obtained by dividing a voltage output from the output terminal in accordance with a second voltage ratio, the second voltage ratio is smaller than the first voltage ratio;
a first comparison amplifier which compares a reference voltage with the first monitor voltage, and outputs a first activation signal if the first monitor voltage is lower than the reference voltage;
a second comparison amplifier which compares the reference voltage with the second monitor voltage, and outputs a second activation signal if the second monitor voltage is lower than the reference voltage but outputs a second deactivation signal if the second monitor voltage is equal to or more than the reference voltage; and
a control circuit which outputs a control clock signal to the first booster circuit, the control clock signal causing the first booster circuit to perform boosting operation with a first boosting capability when the first activation signal is input, causing the first booster circuit to perform boosting operation with a second boosting capability lower than the first boosting capability when the first deactivation signal is input and the second activation signal is input, and causing the first booster circuit to be deactivated when the second deactivation signal is input,
wherein the control circuit outputs the control clock signal so as to cause the first booster circuit to compulsorily perform the boosting operation with the first boosting capability in response to the output signal of the second comparison amplifier after a lapse of a prescribed period since the first booster circuit is started to perform the boosting operation with the first boosting capability in response to the first activation signal of the first comparison amplifier.

2. The power supply circuit according to claim 1, wherein the control circuit outputs the control clock signal in response to an enable signal so as to cause the first booster circuit to compulsorily perform the boosting operation with the first boosting capability in response to the output signal of the second comparison amplifier.

3. The power supply circuit according to claim 2, wherein the control circuit comprises:
a signal terminal which outputs the control clock signal;
a first AND circuit to which the enable signal and an output signal of the first comparison amplifier are input;
a second AND circuit to which an output signal of the first AND circuit and an output signal of the second comparison amplifier are input;
a third AND circuit to which an output signal of the second AND circuit and a first clock signal are input, and which has an output connected to the signal terminal;
an inverter circuit to which the output signal of the second AND circuit is input; and
a fourth AND circuit to which an output signal of the inverter circuit and a second clock signal are input, and which has an output connected to the signal terminal,
wherein the second clock signal has a frequency set to be smaller than a frequency of the first clock signal before the lapse of the prescribed period, and to be equal to the frequency of the first clock signal after the lapse of the prescribed period.

4. A power supply circuit comprising:
an output terminal which outputs a set voltage;
a first booster circuit which boosts and outputs a voltage supplied from a power supply;
an nMOS transistor which is connected between output of the first booster circuit and the output terminal;
a second booster circuit which boosts the voltage output by the first booster circuit and outputs the boosted voltage to a gate of the nMOS transistor;
a voltage divider circuit which outputs a first monitor voltage obtained by dividing a voltage output from the output terminal in accordance with a first voltage ratio, and outputs a second monitor voltage obtained by dividing a voltage output from the output terminal in accordance with a second voltage ratio, the second voltage ratio is smaller than the first voltage ratio;
a first comparison amplifier which compares a reference voltage with the first monitor voltage, and outputs a first activation signal if the first monitor voltage is lower than the reference voltage;
a second comparison amplifier which compares the reference voltage with the second monitor voltage, and outputs a second activation signal if the second monitor voltage is lower than the reference voltage but outputs a second deactivation signal if the second monitor voltage is equal to or more than the reference voltage; and
a control circuit which outputs a control clock signal to the first booster circuit, the control clock signal causing the first booster circuit to perform boosting operation with a first boosting capability when the first activation signal is input, causing the first booster circuit to perform boosting operation with a second boosting capability lower than the first boosting capability when the first deactivation signal is input and the second activation signal is input, and causing the first booster circuit to be deactivated when the second deactivation signal is input,
wherein after a lapse of a prescribed period since the first monitor voltage first exceeds the reference voltage after the first booster circuit is started to perform the boosting operation with the first boosting capability in response to the first activation signal of the first comparison amplifier, the control circuit outputs the control clock signal so as to cause the first booster circuit to compulsorily perform the boosting operation with the first boosting capability in response to the output signal of the second comparison amplifier.

5. The power supply circuit according to claim 4, wherein the control circuit outputs the control clock signal in response to an enable signal so as to cause the first booster circuit to compulsorily perform the boosting operation with the first boosting capability in response to the output signal of the second comparison amplifier.

6. The power supply circuit according to claim 5, wherein the control circuit comprises:
a signal terminal which outputs the control clock signal;
a first AND circuit to which the enable signal and an output signal of the first comparison amplifier are input;
a second AND circuit to which an output signal of the first AND circuit and an output signal of the second comparison amplifier are input;
a third AND circuit to which an output signal of the second AND circuit and a first clock signal are input, and which has an output connected to the signal terminal;
an inverter circuit to which the output signal of the second AND circuit is input; and
a fourth AND circuit to which an output signal of the inverter circuit and a second clock signal are input, and which has an output connected to the signal terminal,
wherein the second clock signal has a frequency set to be smaller than a frequency of the first clock signal before the lapse of the prescribed period, and to be equal to the frequency of the first clock signal after the lapse of the prescribed period.

7. A NAND-type flash memory comprising:
a memory cell array;
a bit-line control circuit which writes and reads data to and from the memory cell array;
a row decoder which controls voltages of a control gate and a select gate for the memory cell array;
a substrate voltage control circuit which controls a voltage of a substrate having the memory cell array formed thereon; and
a power supply circuit which boosts a voltage supplied from a power supply and supplies the boosted voltage to the bit-line control circuit, the row decoder and the substrate voltage control circuit,
wherein the power supply circuit comprising:
an output terminal which outputs a set voltage;
a first booster circuit which boosts and outputs a voltage supplied from a power supply;
an nMOS transistor which is connected between output of the first booster circuit and the output terminal;
a second booster circuit which boosts the voltage output by the first booster circuit and outputs the boosted voltage to a gate of the nMOS transistor;
a voltage divider circuit which outputs a first monitor voltage obtained by dividing a voltage output from the output terminal in accordance with a first voltage ratio, and outputs a second monitor voltage obtained by dividing a voltage output from the output terminal in accordance with a second voltage ratio, the second voltage ratio is smaller than the first voltage ratio;
a first comparison amplifier which compares a reference voltage with the first monitor voltage, and outputs a first activation signal if the first monitor voltage is lower than the reference voltage;
a second comparison amplifier which compares the reference voltage with the second monitor voltage, and outputs a second activation signal if the second monitor voltage is lower than the reference voltage but outputs a second deactivation signal if the second monitor voltage is equal to or more than the reference voltage; and
a control circuit which outputs a control clock signal to the first booster circuit, the control clock signal causing the first booster circuit to perform boosting operation with a first boosting capability when the first activation signal is input, causing the first booster circuit to perform boosting operation with a second boosting capability lower than the first boosting capability when the first deactivation signal is input and the second activation signal is input, and causing the first booster circuit to be deactivated when the second deactivation signal is input,
wherein the control circuit outputs the control clock signal so as to cause the first booster circuit to compulsorily perform the boosting operation with the first boosting capability in response to the output signal of the second comparison amplifier after a lapse of a prescribed period since the first booster circuit is started to perform the boosting operation with the first boosting capability in response to the first activation signal of the first comparison amplifier.

8. The NAND-type flash memory according to claim 7, wherein the control circuit outputs the control clock signal in response to an enable signal so as to cause the first booster circuit to compulsorily perform the boosting operation with the first boosting capability in response to the output signal of the second comparison amplifier.

9. The NAND-type flash memory according to claim 8, wherein the control circuit comprises:
a signal terminal which outputs the control clock signal;
a first AND circuit to which the enable signal and an output signal of the first comparison amplifier are input;
a second AND circuit to which an output signal of the first AND circuit and an output signal of the second comparison amplifier are input;
a third AND circuit to which an output signal of the second AND circuit and a first clock signal are input, and which has an output connected to the signal terminal;
an inverter circuit to which the output signal of the second AND circuit is input; and
a fourth AND circuit to which an output signal of the inverter circuit and a second clock signal are input, and which has an output connected to the signal terminal,
wherein the second clock signal has a frequency set to be smaller than a frequency of the first clock signal before the lapse of the prescribed period, and to be equal to the frequency of the first clock signal after the lapse of the prescribed period.

10. A NAND-type flash memory comprising:
a memory cell array;
a bit-line control circuit which writes and reads data to and from the memory cell array;
a row decoder which controls voltages of a control gate and a select gate for the memory cell array;
a substrate voltage control circuit which controls a voltage of a substrate having the memory cell array formed thereon; and
a power supply circuit which boosts a voltage supplied from a power supply and supplies the boosted voltage to the bit-line control circuit, the row decoder and the substrate voltage control circuit,
wherein the power supply circuit comprising:
an output terminal which outputs a set voltage;
a first booster circuit which boosts and outputs a voltage supplied from a power supply;
an nMOS transistor which is connected between output of the first booster circuit and the output terminal;
a second booster circuit which boosts the voltage output by the first booster circuit and outputs the boosted voltage to a gate of the nMOS transistor;
a voltage divider circuit which outputs a first monitor voltage obtained by dividing a voltage output from the output terminal in accordance with a first voltage ratio, and outputs a second monitor voltage obtained by dividing a voltage output from the output terminal in accordance with a second voltage ratio, the second voltage ratio is smaller than the first voltage ratio;
a first comparison amplifier which compares a reference voltage with the first monitor voltage, and outputs a first activation signal if the first monitor voltage is lower than the reference voltage;
a second comparison amplifier which compares the reference voltage with the second monitor voltage, and outputs a second activation signal if the second monitor voltage is lower than the reference voltage but outputs a second deactivation signal if the second monitor voltage is equal to or more than the reference voltage; and
a control circuit which outputs a control clock signal to the first booster circuit, the control clock signal causing the first booster circuit to perform boosting operation with a first boosting capability when the first activation signal is input, causing the first booster circuit to perform boosting operation with a second boosting capability lower than the first boosting capability when the first deactivation signal is input and the second activation signal is input, and causing the first booster circuit to be deactivated when the second deactivation signal is input,
wherein after a lapse of a prescribed period since the first monitor voltage first exceeds the reference voltage after the first booster circuit is started to perform the boosting operation with the first boosting capability in response to the first activation signal of the first comparison amplifier, the control circuit outputs the control clock signal so as to cause the first booster circuit to compulsorily perform the boosting operation with the first boosting capability in response to the output signal of the second comparison amplifier.

11. The NAND-type flash memory according to claim 10, wherein the control circuit outputs the control clock signal in response to an enable signal so as to cause the first booster circuit to compulsorily perform the boosting operation with the first boosting capability in response to the output signal of the second comparison amplifier.

12. The NAND-type flash memory according to claim 11, wherein the control circuit comprises:
a signal terminal which outputs the control clock signal;
a first AND circuit to which the enable signal and an output signal of the first comparison amplifier are input;
a second AND circuit to which an output signal of the first AND circuit and an output signal of the second comparison amplifier are input;
a third AND circuit to which an output signal of the second AND circuit and a first clock signal are input, and which has an output connected to the signal terminal;
an inverter circuit to which the output signal of the second AND circuit is input; and
a fourth AND circuit to which an output signal of the inverter circuit and a second clock signal are input, and which has an output connected to the signal terminal,
wherein the second clock signal has a frequency set to be smaller than a frequency of the first clock signal before the lapse of the prescribed period, and to be equal to the frequency of the first clock signal after the lapse of the prescribed period.
